(19) United States
(12) Patent Application Publication
(10) Pub. No.: US 2026/0092969 A1
(43) Pub. Date: Apr. 2, 2026

(54) PROBER, METHOD FOR CONTROLLING PROBER, INSPECTION SYSTEM, AND METHOD FOR CONTROLLING INSPECTION SYSTEM

(71) Applicant: Tokyo Electron Limited, Tokyo (JP)

(72) Inventors: Shingo MORITA, Tokyo (JP); Yoshinori FUJISAWA, Kumamoto (JP); Yoichi SHIMIZU, Austin, TX (US)

(21) Appl. No.: 19/371,540

(22) Filed: Oct. 28, 2025

Related U.S. Application Data
(63) Continuation of application No. PCT/JP2024/016069, filed on Apr. 24, 2024.

(30) Foreign Application Priority Data
May 8, 2023 (JP) 2023-076645

(51) Int. Cl. G01R 31/28; G01R 1/073

(52) U.S. Cl. CPC G01R 31/2887; G01R 1/07342; G01R 31/2891

(57) ABSTRACT

A prober includes a support configured to support an inspection target; a driver configured to move the support and adjust a posture of the support; and a controller including a memory and a processor coupled to the memory. The processor is configured to perform controlling the driver to position the inspection target at a predetermined position, and inspecting the inspection target in accordance with a measurement result of characteristics of the inspection target.

### CROSS-REFERENCE TO RELATED APPLICATIONS

This application is a continuation application of International Application No. PCT/JP2024/016069, filed on Apr. 24, 2024, and designated the U.S., which is based upon and claims priority to Japanese Patent Application No. 2023-076645, filed on May 8, 2023, the entire contents of which are incorporated herein by reference.

### BACKGROUND

### 1. Field of the Invention

The present disclosure relates to a prober, a method for controlling the prober, an inspection system, and a method for controlling the inspection system.

### 2. Description of the Related Art

A semiconductor inspection system for inspecting a semiconductor includes, for example, an inspection device (tester) configured to electrically inspect a measurement target, and a prober configured to move the measurement target to a position for inspection by the tester. See, for example, Japanese Laid-Open Patent Application Publication No. 2008-004940 and PCT Japanese Translation Patent Publication No. 2007-538263.

### SUMMARY

According to the present disclosure, a prober includes: a support configured to support an inspection target; a driver configured to move the support and adjust a posture of the support; and a controller including a memory and a processor coupled to the memory. The processor is configured to perform (a) controlling the driver to position the inspection target at a predetermined position, and (b) inspecting the inspection target in accordance with a measurement result of characteristics of the inspection target.

### BRIEF DESCRIPTION OF THE DRAWINGS

FIG. 1 is a schematic diagram of an inspection system according to the present embodiment.

FIG. 2 is a diagram illustrating an overall configuration of the inspection system according to the present embodiment.

FIG. 3 is a diagram for describing a hardware configuration of a controller in a prober included in the inspection system according to the present embodiment.

FIG. 4 is a diagram for describing a hardware configuration of a measurement controller in a meter included in the inspection system according to the present embodiment.

FIG. 5 is a flow diagram (part 1) for describing a process of the inspection system according to the present embodiment.

FIG. 6 is a flow diagram (part 2) for describing the process of the inspection system according to the present embodiment.

FIG. 7 is a flow diagram (part 3) for describing the process of the inspection system according to the present embodiment.

FIG. 8 is a diagram for describing an operating rate of an arithmetic unit when the inspection system according to the present embodiment is operated.

FIG. 9 is a diagram for describing an operating rate of an arithmetic unit when an inspection system according to a comparative example is operated.

FIG. 10 is a schematic diagram of the inspection system of the comparative example.

FIG. 11 is a flow diagram (part 1) for describing a process of the inspection system according to the comparative example.

FIG. 12 is a flow diagram (part 2) for describing the process of the inspection system according to the comparative example.

FIG. 13 is a flow diagram (part 3) for describing the process of the inspection system according to the comparative example.

### DETAILED DESCRIPTION OF THE DISCLOSURE

The present disclosure provides a technique of allowing a prober to be multifunctional.

Hereinafter, embodiments of the present disclosure will be described with reference to the attached drawings. However, the present disclosure is not limited to these embodiments, and is intended to be what is indicated by claims recited and to include all modifications within the meaning and scope equivalent to the claims.

With respect to descriptions of the specification and drawings for each embodiment, components having substantially the same or corresponding functional configuration may be indicated by the same or corresponding reference numerals, and thus, redundant description thereof may be omitted. For facilitating understanding, the scale of each part in the drawings may differ from the actual scale of that part.

### Inspection System

An inspection system according to the present embodiment will be described. The inspection system according to the present embodiment includes a prober and a meter configured to measure characteristics of an inspection target. The prober in the inspection system according to the present embodiment includes: a support configured to support an inspection target; a driver configured to move the support and adjust a posture of the support; and a controller including a memory and a processor coupled to the memory. The processor included in the controller of the inspection system according to the present embodiment is configured to perform (a) controlling the driver to position the inspection target at a predetermined position. Also, the processor included in the controller of the inspection system according to the present embodiment is configured to perform (b) inspecting the inspection target in accordance with a measurement result of characteristics of the inspection target. The measurement result is obtained from the meter in the inspection system according to the present embodiment.

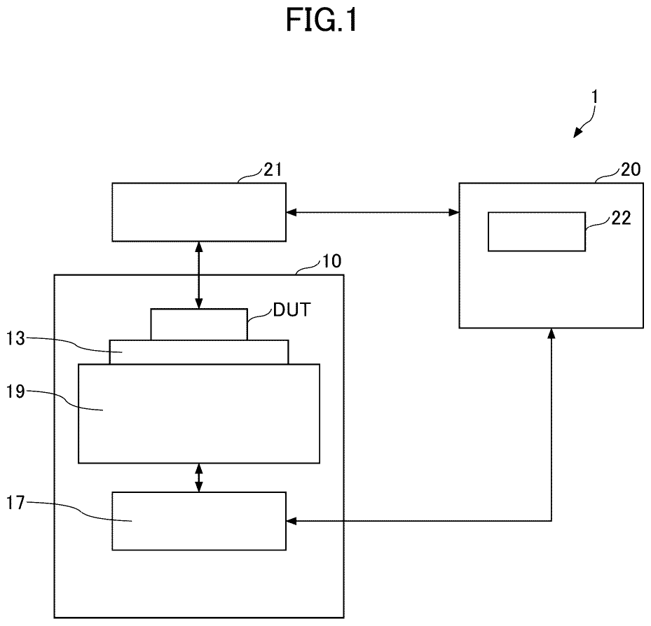

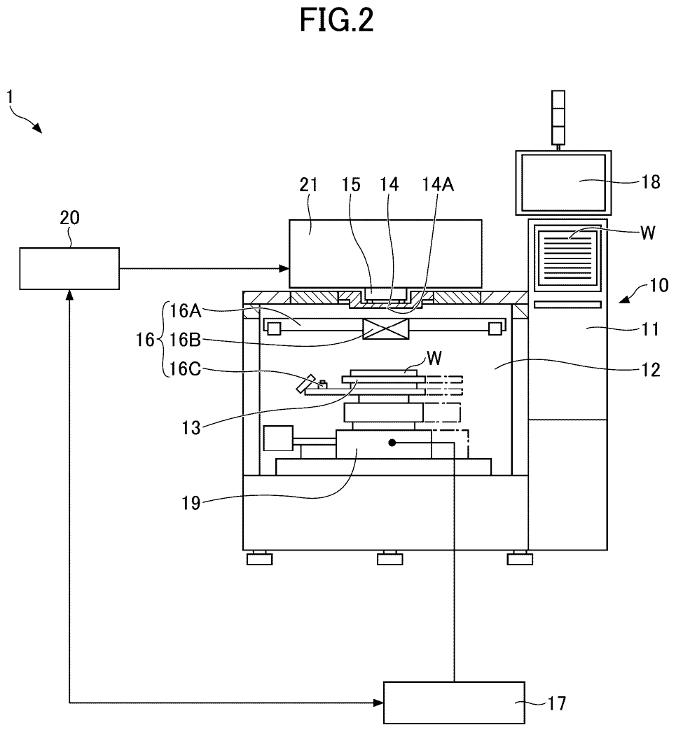

FIG. 1 is a schematic diagram of an inspection system 1, which is an example of the inspection system according to the present embodiment. FIG. 2 is a diagram illustrating an overall configuration of the inspection system 1.

The inspection system 1 is configured to inspect, for example, a device formed on a semiconductor substrate. The inspection system 1 includes a prober 10 and a meter 20.

The prober 10 is configured to convey an inspection target DUT (device under test) such that the inspection target DUT can be measured by the meter 20. In other words, the prober 10 moves the inspection target DUT to a predetermined position, e.g., a position at which the inspection target DUT can be measured by the meter 20. Then, the prober 10 adjusts the inspection target DUT to have a predetermined posture, e.g., a posture in which a probe 14A can contact the inspection target DUT such that the inspection target DUT can be measured by the meter 20. As described above, the prober 10 positions the inspection target DUT such that the inspection target DUT can be measured by the meter 20.

Also, the prober 10 controls the overall inspection in the inspection system 1. The prober 10 controls the meter 20 to perform a predetermined inspection. Then, the prober 10 performs the inspection of the inspection target DUT in accordance with a measurement result from the meter 20.

The meter 20 is configured to measure electrical characteristics of the inspection target DUT.

### Prober 10

The prober 10 conveys the inspection target DUT. Also, the prober 10 aligns the inspection target DUT with the probe 14A of a probe card 14 such that the inspection target DUT can be measured by the meter 20.

The prober 10 includes a loader chamber 11 and a prober chamber 12. The prober 10 conveys a wafer W, i.e., the inspection target DUT, from the loader chamber 11. The prober chamber 12 is next to the loader chamber 11. The wafer W conveyed from the loader chamber 11 is inspected in the prober chamber 12 for electric characteristics.

The prober 10 includes a display 18. The display 18 is configured to display an inspection result and the like.

The prober chamber 12 of the prober 10 includes a support 13, the probe card 14, an insert ring 15, an alignment mechanism 16, and a driver 19.

The support 13 is configured to support the wafer W, i.e., the inspection target DUT. The driver 19 is configured to move the support 13 in directions of three axes orthogonal to each other, i.e., an X axis, a Y axis, and a Z axis, and rotate the support about the X axis, the Y axis, and the Z axis. For example, an X-axis direction and a Y-axis direction are horizontal directions, and a Z-axis direction is a vertical direction. When the driver 19 moves and rotates the support 13, the prober 10 aligns the wafer W, i.e., the inspection target DUT, with a plurality of the probes 14A in the probe card 14. In other words, the driver 19 moves the wafer W, i.e., the inspection target DUT, to a predetermined position, and adjusts the wafer W to have a predetermined posture.

The probe card 14 includes the plurality of the probes 14A that are to contact electrodes formed on the wafer W, i.e., the inspection target DUT. Also, the probe card 14 is electrically connected to a test head 21 via the insert ring 15. The probe card 14 is disposed over the support 13.

The alignment mechanism 16 is configured to perform alignment between the probe 14A in the probe card 14 and electrode pads in the wafer W, i.e., the inspection target DUT, supported on the support 13.

The alignment mechanism 16 includes an alignment bridge 16A, a CCD (charge-coupled device) camera 16B, and a CCD camera 16C. The alignment bridge 16A horizontally moves between a back surface and a probe center in the prober chamber 12. The CCD camera 16B is provided at the alignment bridge 16A. The CCD camera 16C is provided laterally of the support 13.

The alignment mechanism 16 performs alignment between the probe card 14 and the wafer W supported on the support 13. The CCD camera 16B moves from the back surface of the prober chamber to the probe center via the alignment bridge 16A. The CCD camera 16B is positioned between the probe card 14 and the support 13. The CCD camera 16B detects the electrode pads included in the wafer W from above while the support 13 moves in the X-axis direction and the Y-axis direction.

After the alignment bridge 16A recedes to the back surface of the prober chamber 12, the CCD camera 16C sequentially detects the predetermined probes 14A from below the probe card 14 while the support 13 moves in the X-axis direction and the Y-axis direction below the probe card 14.

The controller 17 controls various components including the driver 19 and the alignment mechanism 16. The controller 17 is, for example, a computer. The controller 17 controls the driver 19 and the alignment mechanism 16 to perform alignment between the wafer W supported by the support 13 and the plurality of the probes 14A in the probe card 14. Then, the controller 17 controls the driver 19 and the alignment mechanism 16 to electrically contact the plurality of the probes 14A with the electrodes formed on the wafer W.

For example, the inspection system 1 may perform high-or low-temperature inspection of the wafer W by the controller 17 adjusting the temperature in the prober chamber 12.

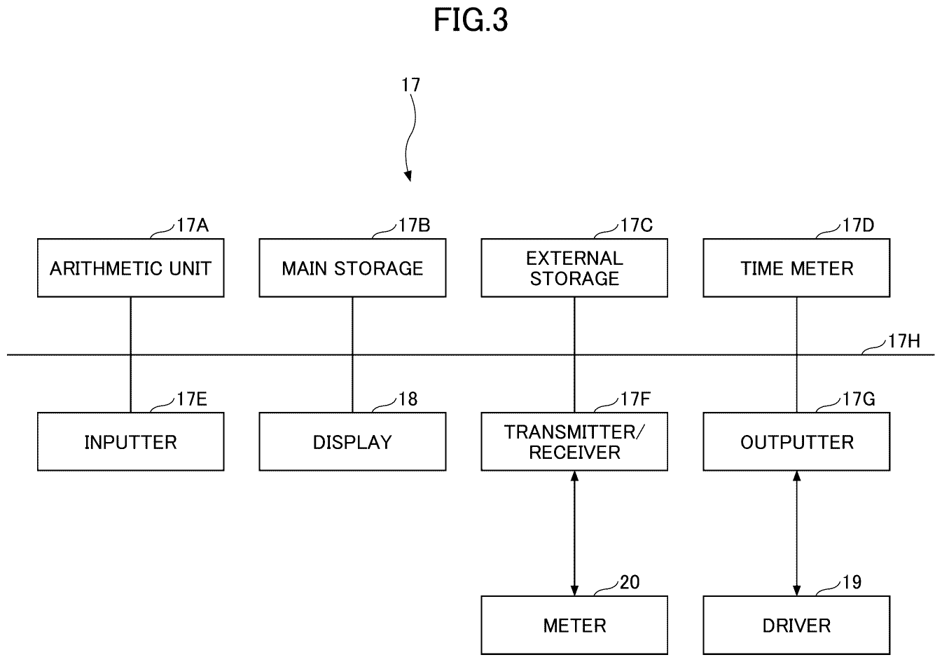

A hardware configuration of the controller 17 will be described. FIG. 3 is a diagram for describing a hardware configuration of the controller 17 in the prober 10 included in the inspection system 1, which is an example of the inspection system according to the present embodiment.

The controller 17 includes an arithmetic unit 17A, a main storage 17B, an external storage 17C, a time meter 17D, an inputter 17E, a transmitter/receiver 17F, and an outputter 17G. The arithmetic unit 17A, the main storage 17B, the external storage 17C, the time meter 17D, the inputter 17E, the transmitter/receiver 17F, and the outputter 17G are connected to a bus 17H.

The display 18 is connected to the controller 17. The display 18 is configured to display, for example, various data input from the inputter 17E, such as, for example, a target temperature at the time of inspection, and image data, such as, for example, images photographed by the CCD camera 16B and the CCD camera 16C.

The arithmetic unit 17A mainly includes, for example, a processor, such as a CPU (Central Processing Unit). The main storage 17B includes, for example, a volatile memory, such as an RAM (Random Access Memory) or the like. The external storage 17C includes, for example, a nonvolatile memory, such as an ROM (Read Only Memory), and a storage medium, such as an HDD (Hard Disk Drive), an SSD (Solid State Drive), or the like.

The arithmetic unit 17A loads, and executes, a program stored in the external storage 17C into the main storage 17B. The arithmetic unit 17A executes the program to control the driver 19. Also, the arithmetic unit 17A executes the program to communicate with the meter 20. Also, the external storage 17C stores results of various processes executed by the arithmetic unit 17A.

The time meter 17D is configured to measure time. The time meter 17D provides the current point in time. The time meter 17D includes a crystal oscillator, a counter configured to count clock pulses oscillated from the crystal oscillator, and a clock. The time meter 17D operates as a timer at a desired time in response to a command from the arithmetic unit 17A. Also, the time meter 17D supplies the current point in time to the arithmetic unit 17A.

For example, when the arithmetic unit 17A sets the counter of the time meter 17D to a predetermined value and starts the timer, the time meter 17D subtracts one from the counter every time a clock pulse occurs, and generates an interrupt signal for the arithmetic unit 17A when the value of the counter becomes zero. When the time meter 17D generates an interrupt signal for the arithmetic unit 17A, the arithmetic unit 17A can measure a predetermined inspection time or the like.

Also, the clock of the time meter 17D counts the clock pulse from a reference point in time, and the arithmetic unit 17A reads the counted value from the time meter 17D. Thus, it is possible to know passage of time from the reference point in time, i.e., the current point in time.

The transmitter/receiver 17F is configured to perform transmission and reception of a signal to and from the meter 20. For example, the arithmetic unit 17A receives (obtains) an inspection result of the wafer W from the meter 20 via the transmitter/receiver 17F. The arithmetic unit 17A transmits a control signal to the meter 20 via the transmitter/receiver 17F. Also, the arithmetic unit 17A receives a control signal from the meter 20 via the transmitter/receiver 17F. Further, the arithmetic unit 17A receives an inspection result of the wafer W from the meter 20 via the transmitter/receiver 17F.

The outputter 17G is configured to communicate with the driver 19. The controller 17 controls the driver 19 via the outputter 17G. The controller 17 may control the support 13.

### Meter 20

The meter 20 is configured to measure electrical characteristics of a semiconductor device formed on the wafer W, i.e., the inspection target DUT. The meter 20 is what is referred to as a semiconductor tester.

The meter 20 includes the test head 21. The test head 21 is electrically connected to the probe card 14 via the insert ring 15. The test head 21 is configured to measure the electrical characteristics of the semiconductor device formed on the wafer W, i.e., the inspection target DUT, via the probe 14A included in the probe card 14.

Also, the meter 20 includes the measurement controller 22 configured to control the meter 20.

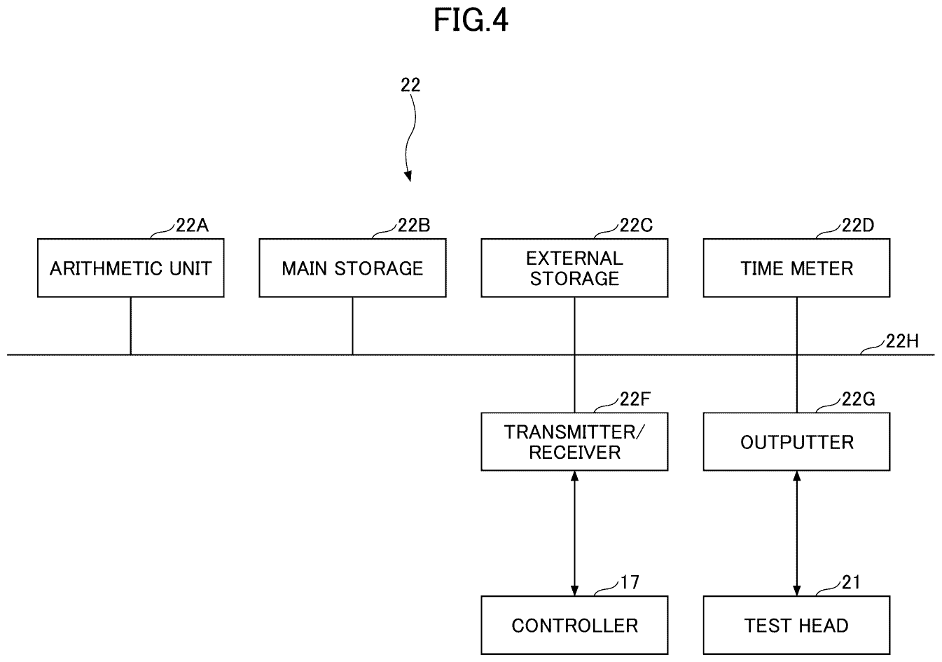

A hardware configuration of the measurement controller 22 will be described. FIG. 4 is a diagram for describing a hardware configuration of the measurement controller 22 in the meter 20 included in the inspection system 1, which is an example of the inspection system according to the present embodiment.

The measurement controller 22 includes an arithmetic unit 22A, a main storage 22B, an external storage 22C, a time meter 22D, a transmitter/receiver 22F, and an outputter 22G. The arithmetic unit 22A, the main storage 22B, the external storage 22C, the time meter 22D, the transmitter/receiver 22F, and the outputter 22G are connected to a bus 22H.

The arithmetic unit 22A mainly includes, for example, a processor, such as a CPU or the like. The main storage 22B includes, for example, a volatile memory, such as an RAM or the like. The external storage 22C includes, for example, a nonvolatile memory, such as an ROM, and a storage medium, such as an HDD, an SSD, or the like.

The arithmetic unit 22A loads, and executes, a program stored in the external storage 22C into the main storage 22B. The arithmetic unit 22A executes the program to control the test head 21. Also, the arithmetic unit 22A executes the program to communicate with the prober 10. Also, the external storage 22C stores results of various processes executed by the arithmetic unit 22A.

The time meter 22D is configured to measure time. The time meter 22D provides the current point in time. The time meter 22D has the same configuration as that of the time meter 17D, and thus detailed description of the time meter 22D is omitted here. For details of the time meter 22D, reference can be made to the description of the time meter 17D.

The transmitter/receiver 22F is configured to perform transmission and reception of a signal to and from the controller 17. For example, the arithmetic unit 22A transmits an inspection result of the wafer W to the controller 17 via the transmitter/receiver 22F. The arithmetic unit 22A receives a control signal from the controller 17 via the transmitter/receiver 22F. Also, the arithmetic unit 22A transmits a control signal to the controller 17 via the transmitter/receiver 22F.

The outputter 22G is configured to communicate with the test head 21. The measurement controller 22 controls the test head 21 via the outputter 22G.

The meter 20 is not limited to a large-scale meter, such as a semiconductor tester, and may be a meter configured to measure electrical characteristics, such as a current meter, a voltage meter, a frequency meter, or the like.

### Operation of Inspection System According to Present Embodiment

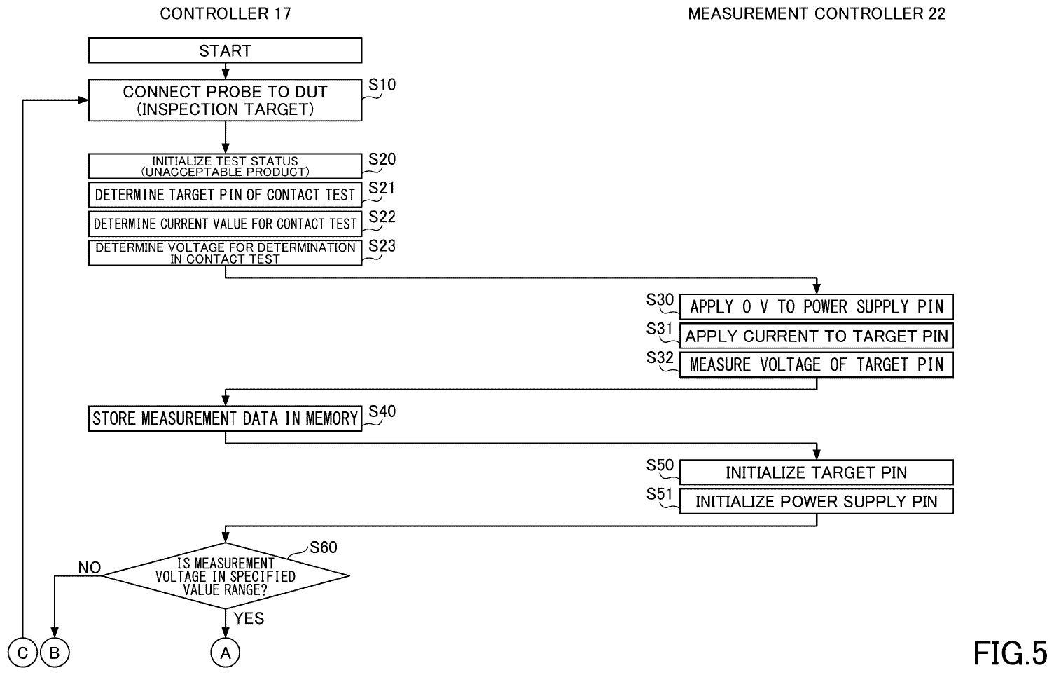

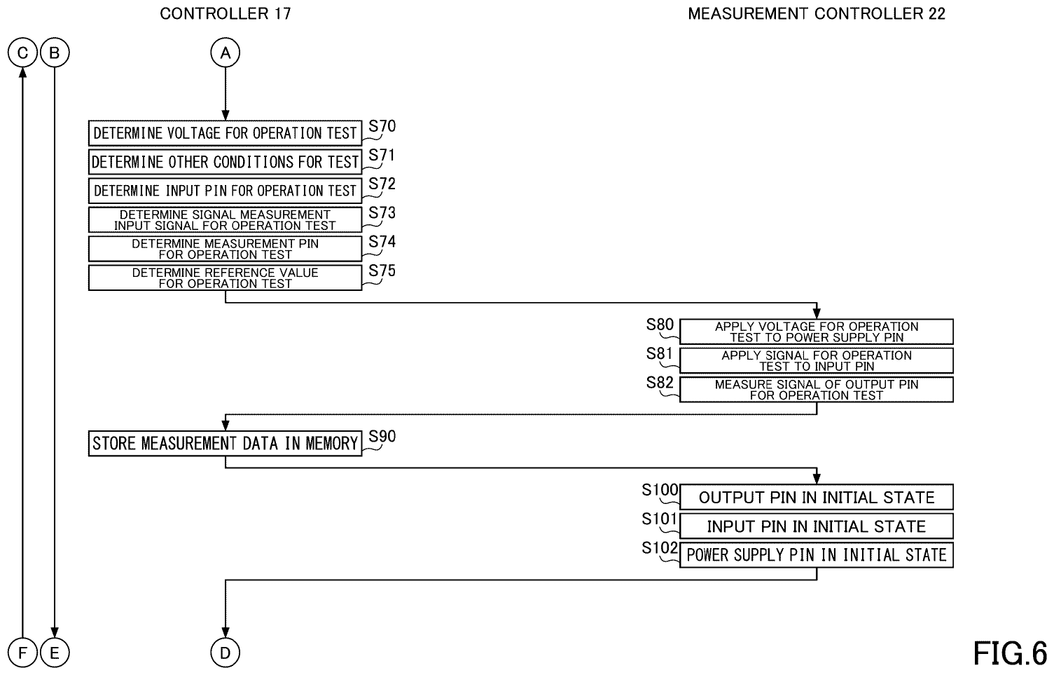

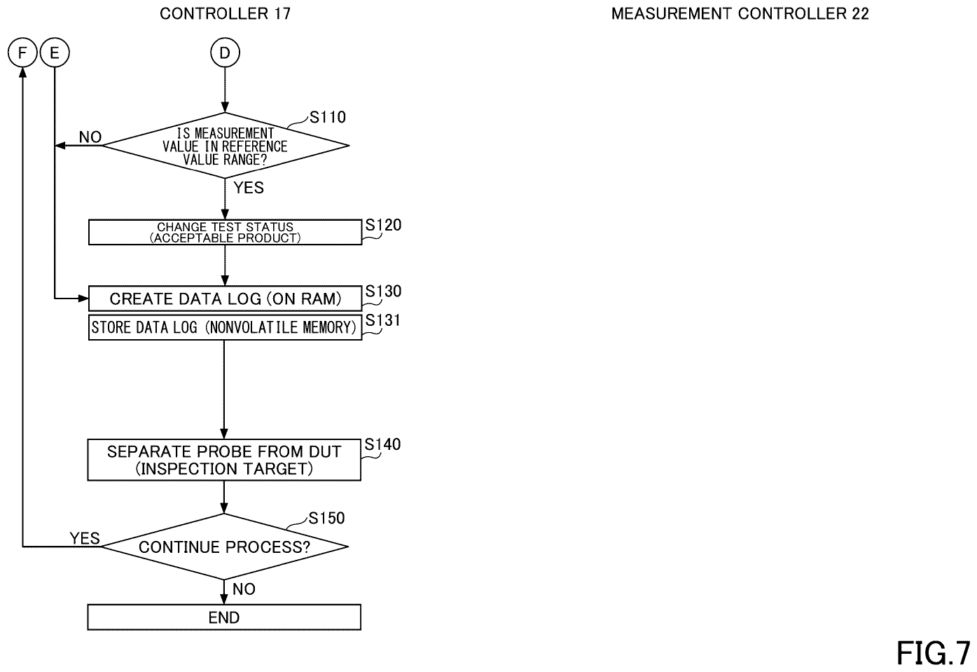

An operation of the inspection system according to the present embodiment will be described. By describing the operation of the inspection system according to the present embodiment, a process executed by the controller of the prober included in the inspection system will be described. Also, by describing the operation of the inspection system according to the present embodiment, processes included in the methods for controlling the inspection system and the prober will be described. The following description will be performed using the inspection system 1, which is an example of the inspection system according to the present embodiment. FIGS. 5 to 7 are flow diagrams for describing a process of the inspection system 1, which is an example of the inspection system according to the present embodiment.

### Step S10

When the inspection system 1 starts a process, the controller 17 controls the driver 19 to connect the probe 14A to the inspection target DUT.

### Steps S20 to S23

Next, the controller 17 initializes a test status (step S20). Specifically, the controller 17 sets the test status to a value indicating an “unacceptable product”. Then, the controller 17 determines a target pin to be subjected to a contact test (step S21). Also, the controller 17 determines a current value for the contact test (step S22). Further, the controller 17 determines a voltage for determination in the contact test (step S23).

The controller 17 transfers the determined target pin, current value, and voltage to the measurement controller 22.

### Steps S30 to S32

Next, the measurement controller 22 controls the test head 21 to apply a voltage of 0 volts to a power supply pin (step S30). Also, the measurement controller 22 controls the test head 21 to apply a current to the pin determined in step S21 (step S31). Then, the measurement controller 22 controls the test head 21 to measure a voltage at the pin to which the current is applied.

The measurement controller 22 transfers a measurement result to the controller 17.

### Step S40

Next, the controller 17 stores the measurement result obtained in step S32 in a measurement data memory.

### Steps S50 to S51

Next, the measurement controller 22 controls the test head 21 to initialize the target pin (step S50). Also, the measurement controller 22 controls the test head 21 to initialize the power supply pin (step S51).

### Step S60

Next, the controller 17 determines whether or not the measured voltage is within a specified value range (step S60). If the measured voltage is within the specified value range (YES in step S60), the controller 17 causes the process to proceed to step S70. If the measured voltage is not within the specified value range (NO in step S60), the controller 17 causes the process to proceed to step S130. When the controller 17 causes the process to proceed to step S130, the inspection target DUT is determined as the “unacceptable product”.

### Steps S70 to S75

If the measured voltage is within the specified value range (YES in step S60), the controller 17 determines a voltage for an operation test (step S70). Also, the controller 17 determines other conditions for the test (step S71). Further, the controller 17 determines an input pin for the operation test (step S72). Also, the controller 17 determines a signal measurement input signal for the operation test (step S73). Further, the controller 17 determines a measurement pin for the operation test (step S74). Also, the controller 17 determines a reference value for the operation test (step S75).

The controller 17 transfers the determined target pin, input signal, reference value, voltage, and the like to the measurement controller 22.

### Steps S80 to S82

Next, the measurement controller 22 controls the test head 21 to apply the voltage for the operation test to the power supply pin (step S80). Also, the measurement controller 22 controls the test head 21 to apply a signal for the operation test to the input pin (step S81). Further, the measurement controller 22 controls the test head 21 to measure a signal of an output pin for the operation test (step S82).

The measurement controller 22 transfers the measured result to the controller 17.

### Step S90

Next, the controller 17 stores a measurement result obtained in step S82 in the measurement data memory.

### Steps S100 to S102

Next, the measurement controller 22 controls the test head 21 to initialize the output pin to be in an initial state (step S100). Also, the measurement controller 22 controls the test head 21 to initialize the input pin to be in an initial state (step S101). Further, the measurement controller 22 controls the test head 21 to initialize the power supply pin to be in an initial state (step S102).

### Step S110

Next, the controller 17 determines whether or not the measured voltage is within a specified value range (step S110). If the measured voltage is within the specified value range (YES in step S110), the controller 17 causes the process to proceed to step S120. If the measured voltage is not within the specified value range (NO in step S110), the controller 17 causes the process to proceed to step S130. When the controller 17 causes the process to proceed to step S130, the inspection target DUT is determined as the “unacceptable product”.

### Step S120

If the measured voltage is within the specified value range (YES in step S110), the controller 17 changes the test status. Specifically, the controller 17 changes the test status to a value indicating an “acceptable product”. By the controller 17 executing step S120, the inspection target DUT is determined as the “acceptable product”.

### Steps S130 to S131

Next, the controller 17 creates a data log on the RAM (step S130). Also, the controller 17 stores the data log in a nonvolatile memory, such as the external storage 17C or the like (step S131).

### Step S140

The controller 17 controls the driver 19 to separate the probe 14A from the inspection target DUT.

### Step S150

Next, the controller 17 determines whether or not the process is to be continued (step S150). If the process is to be continued (YES in step S150), the controller 17 causes the process to return to step S10 and repeats the process. If the process is not to be continued (NO in step S150), the controller 17 ends the process.

### Inspection System of Comparative Example

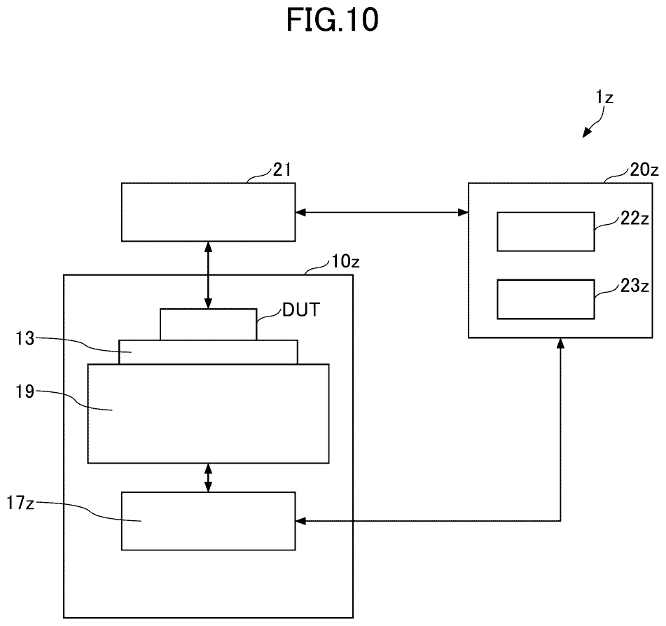

An inspection system of a comparative example will be described. The following description will be performed using an inspection system 1z of the comparative example. FIG. 10 is a schematic diagram of the inspection system 1z of the comparative example.

The inspection system 1z of the comparative example includes a prober 10z and a meter 20z. The prober 10z includes a controller 17z instead of the controller 17 in the prober 10. Also, the meter 20z includes a measurement controller 22z and a data processing controller 23z instead of the measurement controller 22 in the prober 10. Although the measurement controller 22z and the data processing controller 23z are described separately for the purpose of description, these are actually executed by the same arithmetic unit, e.g., the arithmetic unit 22A.

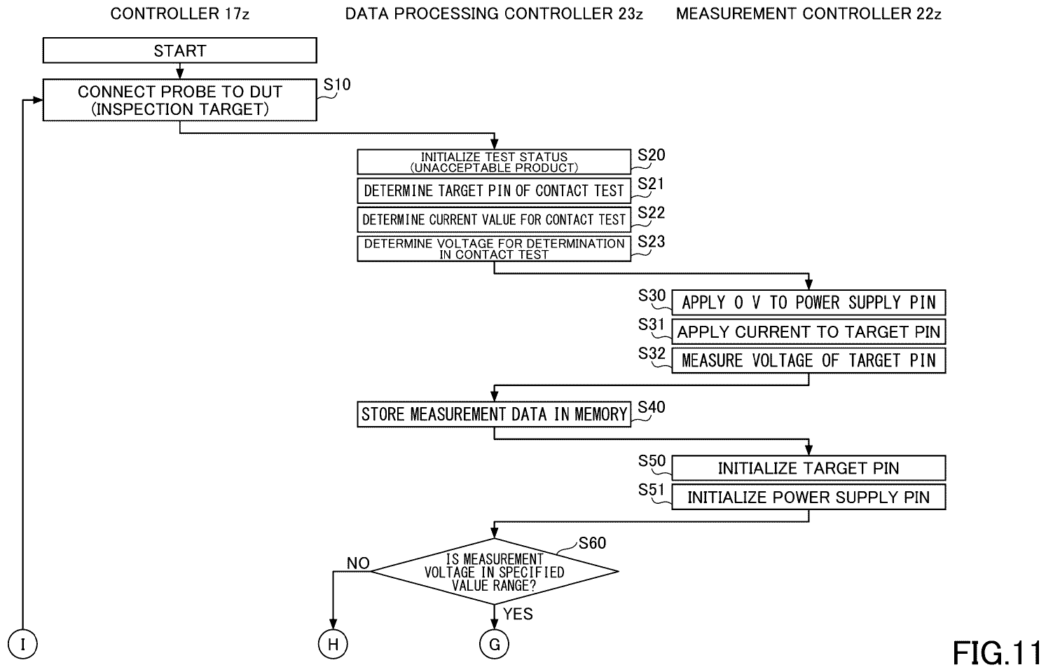

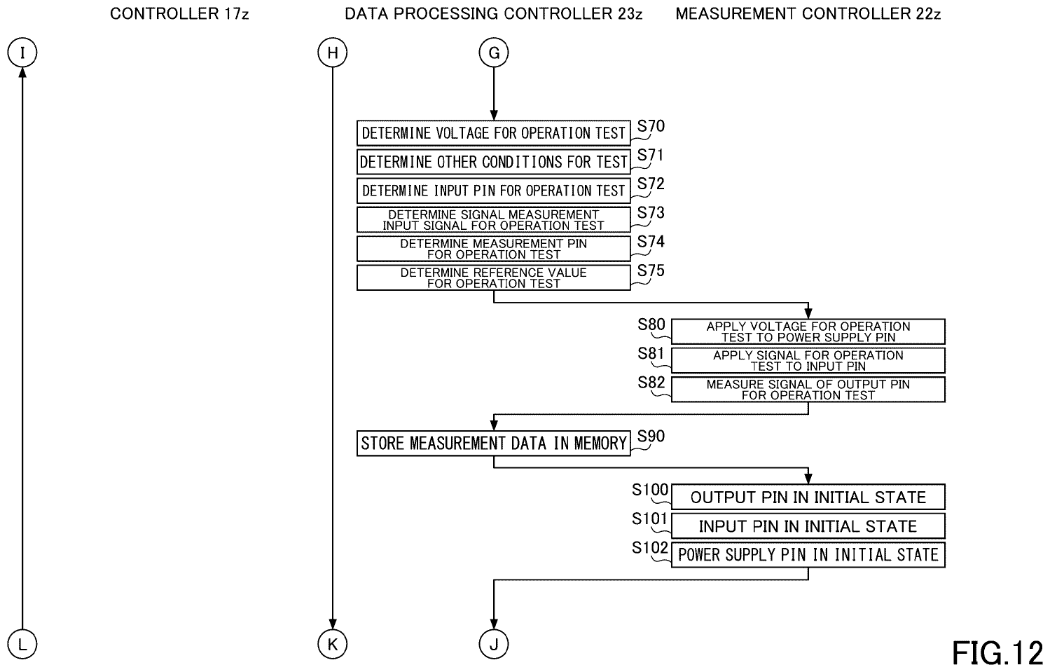

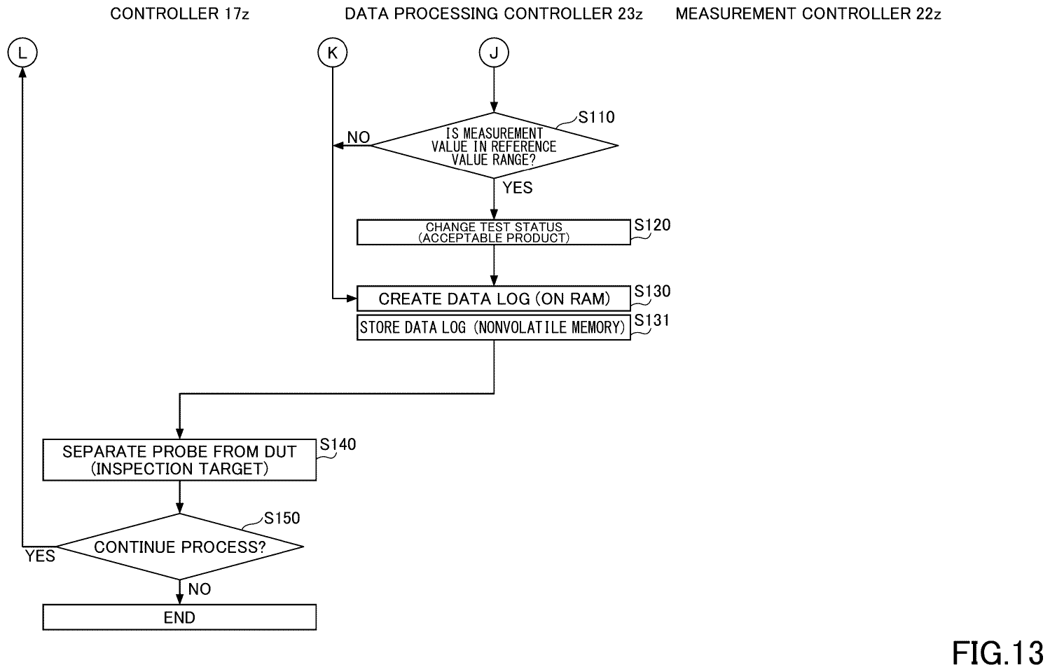

FIGS. 11 to 13 are diagrams for describing a process of the inspection system 1z of the comparative example.

The data processing controller 23z executes part of the process performed by the controller 17. Specifically, the data processing controller 23z executes steps S20 to S23, S40, S60, S70 to S75, S90, S110, S120, and S130 to S131, which are executed by the controller 17.

The controller 17z executes part of the process performed by the controller 17. Specifically, the controller 17z executes steps S10, S140, and S150, which are performed by the controller 17.

The measurement controller 22z executes the same process as in the measurement controller 22.

However, the measurement controller 22z is controlled not by the controller 17 but by the data processing controller 23z. Also, the measurement controller 22z outputs a measurement result to the data processing controller 23z rather than the controller 17.

A typical inspection of a semiconductor device is performed using an apparatus (meter) configured to apply an electric signal to a semiconductor and perform a test, and an apparatus (prober) configured to convey the semiconductor device and connect the semiconductor device to a terminal (probe) for the test. The meter applies an electric signal, and the prober performs positioning. Therefore, the meter and the prober have different roles, and thus suppliers of the meter and the prober are often different.

Also, the inspection of the semiconductor device alternately performs positioning of the inspection target DUT by use of the prober, and inspection of the inspection target DUT by use of the meter. While the inspection is performed by the meter, the prober is in an idling state.

The process performed by the meter includes measurement control processing for controlling hardware configured to generate a test signal and perform measurement, and data processing for determining and processing data. Therefore, the measurement control processing in the inspection system according to the present embodiment is closely related to the meter, and thus is executed by the arithmetic unit included in the meter. In the inspection system according to the present embodiment, the data processing is executed by the arithmetic unit included in the prober that is in an idling state.

Specifically, steps S30 to S32, S50 to S51, S80 to S82, and S100 to S102, which are executed by the measurement controller 22 or the measurement controller 22z, are examples of the measurement control processing described above.

Steps S20 to S23, S40, S60, S70 to S75, S90, S110, S120, and S130 to S131, which are executed by the controller 17 or the data processing controller 23z, are examples of the data processing described above. In other words, the data processing described above is an example of inspecting the inspection target in accordance with the measurement result obtained by measuring characteristics of the inspection target. In the inspection system according to the present embodiment, the data processing is executed by the arithmetic unit included in the prober while the meter is in an idling state during inspection.

Steps S10 and S140, which are executed by the controller 17 or the controller 17z, are examples of controlling the driver 19 to position the inspection target at a predetermined position.

### Operation of Inspection System According to Present Embodiment

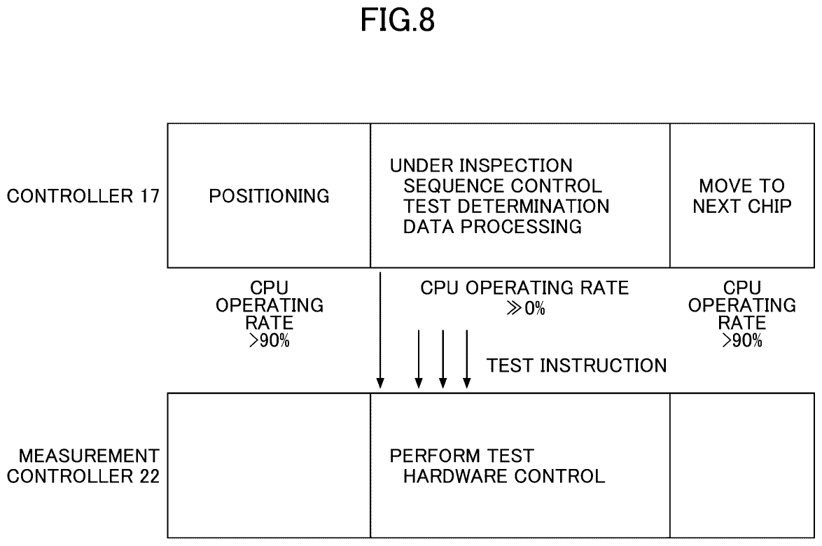

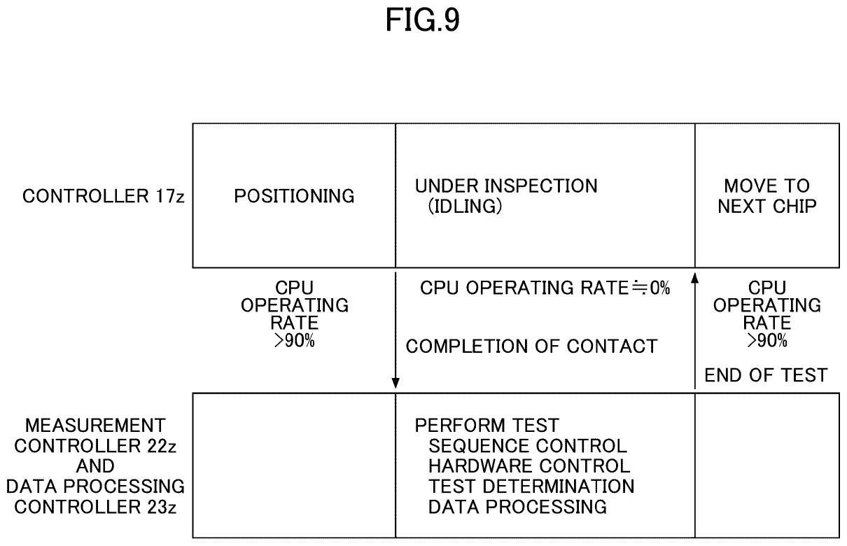

A result of operation of the inspection system according to the present embodiment will be described. FIG. 8 is a diagram for describing a result of operation of the inspection system 1, which is an example of the inspection system according to the present embodiment. FIG. 9 is a diagram for describing a result of operation of the inspection system 1z of the comparative example.

According to the inspection system 1, which is an example of the inspection system according to the present embodiment, the controller 17 in the prober 10 operates at a predetermined operating rate during inspection. Conversely, in the inspection system 1z, the operating rate of the controller 17z in the prober 10z is approximately zero partway through the inspection. Therefore, according to the inspection system according to the present embodiment, it is possible to increase the operating rate of the processor in the controller included in the prober.

As described above, according to the inspection system according to the present embodiment, by performing inspection of the inspection target in the prober, i.e., the prober executing inspection of the inspection target, it is possible to realize multifunctionality of the prober. Also, according to the inspection system according to the present embodiment, by performing data processing in the prober, it is possible to increase the operating rate of the arithmetic unit in the prober. Further, according to the inspection system according to the present embodiment, by the prober performing the processing conventionally performed in the meter, it is possible to reduce a load of the arithmetic unit in the meter and increase a processing speed in the inspection system.

The inspection system according to the present embodiment disclosed herein should be considered to be exemplary and not restrictive in all respects. The above embodiments can be modified and improved in various forms without departing from the scope and intent of claims recited. As long as there is no contradiction, the matters described in the above embodiments can have other configurations, and can be combined with each other.

What is claimed is:

1. A prober, comprising:
a support configured to support an inspection target;
a driver configured to move the support and adjust a posture of the support; and
a controller including a memory and a processor coupled to the memory, wherein
the processor is configured to perform
(a) controlling the driver to position the inspection target at a predetermined position, and
(b) inspecting the inspection target in accordance with a measurement result of characteristics of the inspection target.

2. The prober according to claim 1, wherein
the inspection of (b) includes obtaining the measurement result from a meter configured to measure the characteristics of the inspection target.

3. The prober according to claim 2, wherein
the processor is configured to control measurement in the meter.

4. A method for controlling a prober including a support configured to support an inspection target, a driver configured to move the support and adjust a posture of the support, and a controller including a memory and a processor coupled to the memory, the method comprising:
controlling, by the processor, the driver to position the inspection target at a predetermined position; and
inspecting, by the processor, the inspection target in accordance with a measurement result of characteristics of the inspection target.

5. An inspection system, comprising:
a prober; and
a meter configured to measure characteristics of an inspection target, wherein
the prober includes
a support configured to support an inspection target,
a driver configured to move the support and adjust a posture of the support, and
a controller including a memory and a processor coupled to the memory, and
the processor is configured to perform
(a) controlling the driver to position the inspection target at a predetermined position, and
(b) inspecting the inspection target in accordance with a measurement result of characteristics of the inspection target.

6. The inspection system according to claim 5, wherein
the inspection of (b) includes obtaining the measurement result from the meter.

7. The inspection system according to claim 6, wherein
the processor is configured to control measurement in the meter.

8. A method for controlling the inspection system of claim 5, the method comprising:
controlling, by the processor, the driver to position the inspection target at a predetermined position; and
inspecting, by the processor, the inspection target in accordance with the measurement result of the characteristics of the inspection target.
